(19) United States
(12) Patent Application Publication
(10) Pub. No.: US 2014/0158976 A1
(43) Pub. Date: Jun. 12, 2014

(54) III-N SEMICONDUCTOR-ON-SILICON STRUCTURES AND TECHNIQUES

(71) Applicants: Sansaptak Dasgupta, Hillsboro, OR (US); Han Wui Then, Portland, OR (US); Marko Radosavljevic, Beaverton, OR (US); Niloy Mukherjee, Beaverton, OR (US); Robert S. Chau, Hillsboro, OR (US)

(72) Inventors: Sansaptak Dasgupta, Hillsboro, OR (US); Han Wui Then, Portland, OR (US); Marko Radosavljevic, Beaverton, OR (US); Niloy Mukherjee, Beaverton, OR (US); Robert S. Chau, Hillsboro, OR (US)

(21) Appl. No.: 13/706,473

(22) Filed: Dec. 6, 2012

(51) Int. Cl. H01L 21/36; H01L 29/06

(52) U.S. Cl. CPC H01L 21/36; H01L 29/0684; Y10S 977/762; B82Y 99/00
USPC 257/12; 438/478; 438/479

(57) ABSTRACT

III-N semiconductor-on-silicon integrated circuit structures and techniques are disclosed. In some cases, the structure includes a first semiconductor layer formed on a nucleation layer, the first semiconductor layer including a 3-D GaN layer on the nucleation layer and having a plurality of 3-D semiconductor structures, and a 2-D GaN layer on the 3-D GaN layer. The structure also may include a second semiconductor layer formed on or within the first semiconductor layer, wherein the second semiconductor layer includes AlGaN on the 2-D GaN layer and a GaN layer on the AlGaN layer. Another structure includes a first semiconductor layer formed on a nucleation layer, the first semiconductor layer comprising a 2-D GaN layer on the nucleation layer, and a second semiconductor layer formed on or within the first semiconductor layer, wherein the second semiconductor layer includes AlGaN on the 2-D GaN layer and a GaN layer on the AlGaN layer.

### BACKGROUND

Integrated circuit (IC) design in the deep-submicron process nodes (e.g., 32 nm and beyond) involves a number of non-trivial challenges, and gallium nitride (GaN)-on-silicon (Si) devices have faced particular complications. Continued process scaling will tend to exacerbate such problems.

### BRIEF DESCRIPTION OF THE DRAWINGS

FIG. 1A is a side cross-sectional view of an integrated circuit (IC) configured in accordance with an embodiment of the present invention.

FIG. 1B is a side cross-sectional view of an IC configured in accordance with another embodiment of the present invention.

FIG. 1C is a side cross-sectional view of an IC configured in accordance with another embodiment of the present invention.

FIG. 1D is a side cross-sectional view of an IC configured in accordance with another embodiment of the present invention.

FIG. 2A is a cross-section view of an IC configured in accordance with an embodiment of the present invention.

FIG. 2B is a cross-section view of an IC configured in accordance with another embodiment of the present invention.

FIG. 3A is a cross-section view of an IC configured in accordance with an embodiment of the present invention.

FIG. 3B is a cross-section view of an IC configured in accordance with another embodiment of the present invention.

FIG. 4 illustrates a computing system implemented with integrated circuit structures or devices formed by one or more of the defect density and/or crack density reduction techniques disclosed herein, in accordance with an example embodiment of the present invention.

As will be appreciated, the figures are not necessarily drawn to scale or intended to limit the claimed invention to the specific configurations shown. For instance, while some figures generally indicate straight lines, right angles, and smooth surfaces, an actual implementation of a given embodiment may have less than perfect straight lines, right angles, etc., and some features may have surface topology or otherwise be non-smooth, given real world limitations of integrated circuit (IC) fabrication. In short, the figures are provided merely to show example structures. In the drawings, each identical or nearly identical component that is illustrated in various figures may be represented by a like numeral. For purposes of clarity, not every component may be labeled in every drawing. These and other features of the present embodiments will be understood better by reading the following detailed description, taken together with the figures herein described.

### DETAILED DESCRIPTION

III-N semiconductor-on-silicon integrated circuit structures and techniques are disclosed. In some cases, the structure includes a first semiconductor layer formed on a nucleation layer, the first semiconductor layer including a three-dimensional GaN layer on the nucleation layer and having a plurality of three-dimensional semiconductor structures, and a two-dimensional GaN layer on the three-dimensional GaN layer. The structure also may include a second semiconductor layer formed on or within the first semiconductor layer, wherein the second semiconductor layer includes AlGaN on the two-dimensional GaN layer and a GaN layer on the AlGaN layer. Another structure includes a first semiconductor layer formed on a nucleation layer, the first semiconductor layer comprising a two-dimensional GaN layer on the nucleation layer, and a second semiconductor layer formed on or within the first semiconductor layer, wherein the second semiconductor layer includes AlGaN on the two-dimensional GaN layer and a GaN layer on the AlGaN layer. Some example structures which may be formed using the disclosed techniques may include, but are not necessarily limited to, gallium nitride-on-silicon (GaN-on-Si), aluminum gallium nitride-on-silicon (AlGaN-on-Si), aluminum indium nitride-on-silicon (AlInN-on-Si), etc. In some cases, a given structure provided using the disclosed techniques may exhibit, for example: (1) reduced defect density; (2) reduced surface crack density; and/or (3) improved surface smoothness (e.g., of the top/active layer of the structure). In some cases, defect density may be reduced and surface smoothness improved or otherwise preserved while simultaneously eliminating surface cracks altogether. Numerous configurations and variations will be apparent in light of this disclosure.

General Overview

As previously indicated, there are a number of non-trivial issues that can arise which complicate gallium nitride (GaN)-on-silicon (Si) devices. For instance, one non-trivial issue pertains to the fact that there is a lattice mismatch of approximately 42% between GaN and Si(100) (that is, silicon having a crystal orientation of [100]). The dissimilar lattices of these materials produce threading dislocation defects which inhibit epitaxial growth of low defect density III-N materials on Si(100). Another non-trivial issue pertains to the fact that there is a thermal mismatch of approximately 116% between GaN and Si. This large thermal mismatch, coupled with the high growth temperatures for GaN, results in an undesirably high surface crack density for the top/active epitaxial layers, making them unsuitable for device fabrication. These example complications have precluded use of GaN on Si(100), for example, in system-on-chip (SoC) high-voltage and radio frequency (RF) devices as well as in complementary metal-oxide-semiconductor (CMOS) transistors, among other applications.

One possible approach to addressing these non-trivial issues might utilize multiple aluminum nitride (AlN) layers inserted between GaN growth on Si(100). However, as will be appreciated in light of this disclosure, this approach may be unsuccessful in preventing defects such as threading dislocations from migrating to the top of the resultant stack (e.g., the active layer of the device) and can lead to defect densities in the range of 3×10¹⁰/cm² or greater (e.g., as measured by plan view transmission electron microscopy or PVTEM). Furthermore, the surface smoothness can be severely compromised with the use of such AlN layers, leading to top/active layers with undesirably rough and pitted surfaces which generally are not suitable for device fabrication.

Thus, and in accordance with an embodiment of the present invention, techniques are disclosed herein for providing III-N semiconductor-on-silicon structures. In some cases, the disclosed techniques can be used to provide an integrated circuit (IC) structure which includes a three-dimensional layer of a III-N semiconductor material (e.g., gallium nitride or GaN; aluminum gallium nitride or AlGaN; aluminum indium nitride or AlInN; etc.) that is formed, in the aggregate, from a plurality of three-dimensional semiconductor structures (e.g., islands, nanowires, etc.). This layer of three-dimensional semiconductor structures can be formed using any of a wide variety of techniques (e.g., deposition or epitaxial growth in a three-dimensional growth mode; in-situ patterning; ex-situ patterning; etc.), as discussed below. Thereafter, a two-dimensional layer of a semiconductor material (e.g., GaN, AlGaN, AlInN, etc.) may be grown, layer by layer, over the three-dimensional semiconductor layer, for example, to recover a desired degree of surface smoothness. In some instances, additional layers of similar and/or different semiconductor materials may be provided on such two-dimensional semiconductor layer, for example, to alter the stress state of the total structure. In some further instances, a capping layer of a similar and/or different semiconductor material optionally may be included, as desired for a given application or end use (e.g., electronic devices, optoelectronic applications, etc.). Numerous configurations will be apparent in light of this disclosure.

In some cases, structures provided using the disclosed techniques may exhibit, for example: (1) reduced defect density; (2) reduced surface crack density; and/or (3) improved surface smoothness (e.g., of the top/active layer of the structure). Some structures provided using the disclosed techniques may exhibit a reduced defect density and surface smoothness while having substantially no surface cracks (or an otherwise minimal number of surface cracks). For instance, the disclosed techniques can be used, in one specific example embodiment, to provide a GaN-on-Si(100) structure (that is, GaN on silicon having a crystal orientation of [100]) having a defect density in the range of about 2-3×10⁹/cm² or less. In some such cases, such a reduction in defect density may be achieved while simultaneously reducing surface crack density. For instance, in some example cases, the surface crack density of such a GaN-on-Si(100) structure may be reduced to be in the range of less than or equal to about 200 cracks/mm² (e.g., about 150 cracks/mm² or fewer; about 100 cracks/mm² or fewer; about 50 cracks/mm² or fewer; about 10 cracks/mm² or fewer; about 5 cracks/mm² or fewer; etc.). It should be noted, however, that the claimed invention is not so limited, as in some other cases, surface cracks may be eliminated altogether (e.g., surface crack density may be approximately or equal to zero). In a more general sense, defect density and surface crack density can vary from one embodiment to the next, and the claimed invention is not intended to be limited to any particular range.

Also, as previously noted, some embodiments of structures provided using the disclosed techniques may exhibit improved (or otherwise preserved) surface smoothness. For instance, the disclosed techniques can be used, in one example embodiment, to provide a GaN-on-Si(100) structure having a root mean square (RMS) surface roughness in the range of less than or equal to about 15 nm (e.g., about 12 nm or less; about 6 nm or less; about 3 nm or less; about 2 nm or less; about 1.5 nm or less; etc.), which may provide GaN-on-Si(100) structures, for example, suitable for any of a wide variety of device fabrication processes. Other defect density, surface crack density, and/or surface roughness ranges achievable using the disclosed techniques will depend on a given application and will be apparent in light of this disclosure.

As will be further appreciated in light of this disclosure, some embodiments of the present invention may be used in any of a wide variety of applications or end uses in any of a wide variety of fields, such as, but not limited to: wireless communications/transmissions; power management, conversion, and transmission; electric vehicles; light emitting diodes (LEDs), lasers, and other III-N optoelectronic devices; and/or solid state lighting (SSL). Some embodiments may be used, for example, in system-on-chip (SoC) circuits which may be used in any of a wide range of electronic devices including, but not limited to: smartphones; notebooks; tablets; personal computers (PCs); etc. Also, some embodiments of the present invention may be used in electronic devices, for example, which utilize direct battery high voltage switching transistors (e.g., power management ICs; DC-to-DC conversion in output filters and in drive circuitries; etc.). As will be further appreciated in light of this disclosure, in some cases the disclosed techniques can be used to fabricate GaN-based devices (e.g., electronics, LEDs/lasers, etc.) on a large area Si(100) substrate, which may reduce production cost and/or enable high volume manufacturing. Other suitable uses of one or more embodiments of the present invention will depend on a given application and will be apparent in light of this disclosure.

As will be appreciated in light of this disclosure, and in accordance with an embodiment, use of the disclosed techniques/structure may be detected, for example, by visual or other inspection (e.g., scanning electron microscopy or SEM; transmission electron microscopy or TEM; etc.) and/or materials analysis (e.g., energy-dispersive X-ray spectroscopy or EDX; secondary ion mass spectrometry or SIMS; high-resolution TEM; etc.) of a given IC or other device that has a III-N semiconductor on silicon structure configured as described herein.

Three-Dimensional and Two-Dimensional GaN Structure

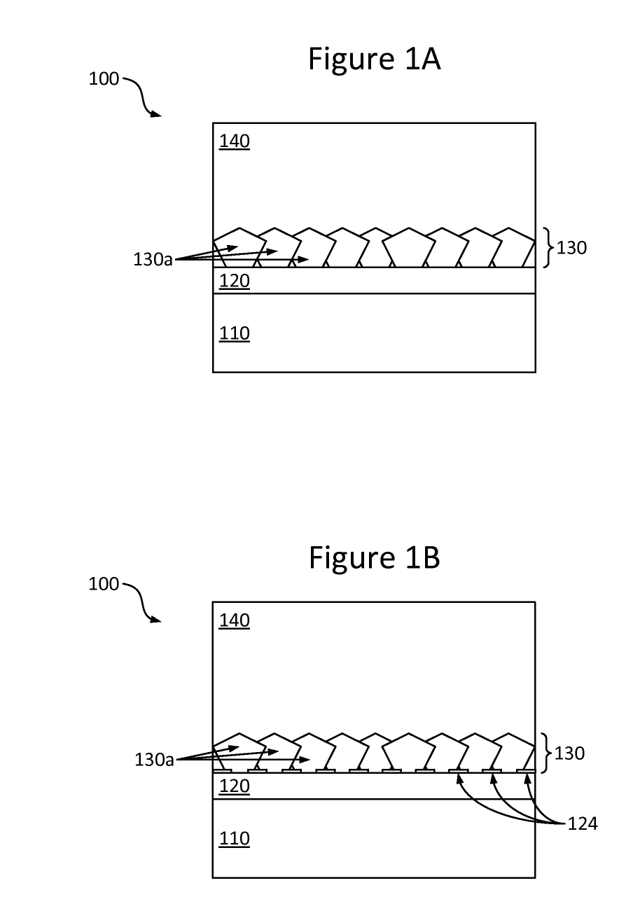

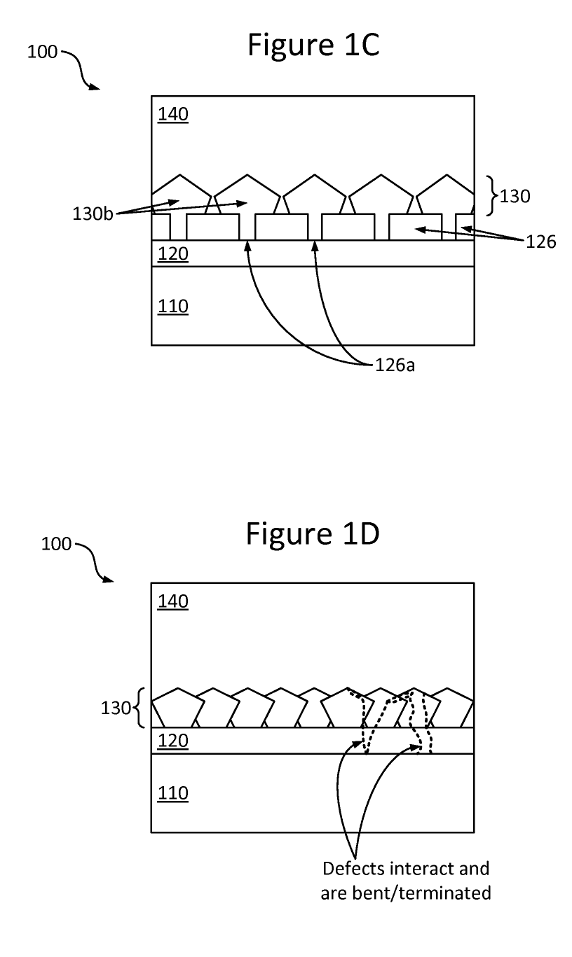

FIG. 1A is a side cross-sectional view of an integrated circuit (IC) 100 configured in accordance with an embodiment of the present invention. As can be seen, IC 100 may include a substrate 110, a nucleation layer 120 disposed on substrate 110, a layer 130 of three-dimensional semiconductor structures disposed on nucleation layer 120, and a two-dimensional semiconductor layer 140 disposed on the three-dimensional semiconductor layer 130. As will be appreciated in light of this disclosure, IC 100 may include additional, fewer, and/or different elements or components from those here described, and the claimed invention is not intended to be limited to any particular IC configurations, but can be used with numerous configurations in numerous applications.

In accordance with an embodiment, substrate 110 may have any of a wide range of configurations. For instance, some suitable configurations for substrate 110 may include, but are not limited to: (1) a bulk substrate; (2) a semiconductor-on-insulator (XOI, where X is a semiconductor material such as silicon, germanium, germanium-enriched silicon, etc.); (3) a wafer; (4) a multi-layered structure; and/or (5) any other suitable configuration, as will be apparent in light of this disclosure. Furthermore, and in accordance with an embodiment, substrate 110 may comprise any of a wide range of materials. Some example suitable materials for substrate 110 may include, but are not necessarily limited to: (1) silicon (Si) having a crystal orientation of [100]—hereinafter referred to as Si(100)—and optionally having an offcut towards the [110] direction of up to about 11° or less; (2) Si having a crystal orientation of [110]—hereinafter referred to as Si(110)—and optionally having an offcut towards the [111] direction of up to about 6° or less; and/or (3) Si having a crystal orientation of [111]—hereinafter referred to as Si(111). However, the claimed invention is not so limited, and other suitable materials, crystallographic orientations, and/or configurations for substrate 110 will depend on a given application and will be apparent in light of this disclosure.

As previously noted, and in accordance with an embodiment, a nucleation layer 120 may be disposed on substrate 110, for example, to help begin growth on IC 100 of one or more layers of semiconductor material (e.g., one or more III-N semiconductor materials such as GaN, AlGaN, AlInN, etc., as discussed below). In some cases in which substrate 110 comprises Si(100), for example, nucleation layer 120 may comprise a semiconductor material such as, but not limited to, aluminum nitride (AlN), AlGaN, an alloy of any of the aforementioned, and/or a combination of any of the aforementioned. However, the claimed invention is not so limited, and other suitable materials for nucleation layer 120 will depend on a given material composition of substrate 110 and/or layer 130 (discussed below) and will be apparent in light of this disclosure. In a more general sense, layer 120 may be any material suitable for providing nucleation sites to layer 130.

In accordance with an embodiment, nucleation layer 120 may be formed (e.g., deposited, grown, etc.) on substrate 110 using any of a wide range of techniques. Some example suitable formation techniques may include, but are not limited to, molecular beam epitaxy (MBE), metalorganic vapor phase epitaxy (MOVPE), etc. Also, and in accordance with an embodiment, nucleation layer 120 may be provided with any given thickness, as desired for a given application or end use. In some embodiments, nucleation layer 120 may have a thickness in the range of about a monolayer to about 300 nm or greater (e.g., about 100-200 nm or greater, or any other sub-range within the range of about 1-300 nm or greater). In some cases, nucleation layer 120 may have a substantially uniform thickness across the topology provided by the underlying substrate 110. However, the claimed invention is not so limited, as in some other instances, nucleation layer 120 may be provided with a non-uniform or otherwise varying thickness over such topology. For instance, in some cases a first portion of nucleation layer 120 may have a thickness within a first range while a second portion thereof has a thickness within a second, different range. Other suitable formation techniques and/or thickness ranges for nucleation layer 120 will depend on a given application and will be apparent in light of this disclosure.

As previously noted, and in accordance with an embodiment, a three-dimensional semiconductor layer 130 may be disposed on nucleation layer 120. In some cases, semiconductor layer 130 may comprise, for example, a III-N semiconductor material such as, but not limited to: (1) gallium nitride (GaN); (2) aluminum gallium nitride (AlGaN) having an Al concentration in the range of about 0% to 10% (e.g., about 5% or less); (3) aluminum indium nitride (AlInN) having an Al concentration in the range of about 0% to 10% (e.g., about 5% or less); and/or (4) a combination of any of the aforementioned. Other suitable materials for three-dimensional semiconductor layer 130 will depend on a given material composition of nucleation layer 120 and/or application of IC 100 and will be apparent in light of this disclosure.

In accordance with an embodiment, three-dimensional semiconductor layer 130 may have any of a wide range of configurations. For example, three-dimensional semiconductor layer 130 may comprise, in accordance with an embodiment, a plurality of three-dimensional semiconductor structures (e.g., island-like structures 130a, nanowires 130b, etc., discussed below) which, in the aggregate, define a three-dimensional layer of one or more semiconductor materials on nucleation layer 120. Furthermore, and in accordance with an embodiment, three-dimensional semiconductor layer 130 may be provided with any thickness, as desired for a given application or end use. For instance, in some example embodiments, three-dimensional semiconductor layer 130 may have a thickness in the range of about 1-250 nm or greater (e.g., about 50-100 nm or greater; about 100-150 nm or greater; about 150-200 nm or greater; about 200-250 nm or greater; or any other sub-range within the range of about 1-250 nm or greater). As will be appreciated in light of this disclosure, and in accordance with an embodiment, three-dimensional semiconductor layer 130 may be provided as a generally discontinuous layer (e.g., by virtue of its constituent structures 130a, 130b, etc., discussed below). The thickness of three-dimensional semiconductor layer 130 may be varied as desired across the underlying topology (e.g., provided by the underlying nucleation layer 120). Other suitable structural configurations and/or thickness ranges for three-dimensional semiconductor layer 130 will depend on a given application and will be apparent in light of this disclosure.

As can be seen from FIG. 1A, for example, in some cases, three-dimensional semiconductor layer 130 may comprise a plurality of island-like semiconductor structures 130a. In accordance with an embodiment, the island-like structures 130a may be located sufficiently proximate one another so as to generally overlap or otherwise merge with another while remaining substantially discrete so as not to form a continuous layer across the underlying topology of nucleation layer 120. In accordance with an embodiment, the plurality of island-like structures 130a may be formed on nucleation layer 120 using any of a wide range of techniques, as discussed below. In some instances, a given island-like structure 130a may exhibit a generally polygonal cross-sectional geometry (e.g., an approximately hexagonal cross-sectional geometry as viewed from a top-down vantage point). However, the claimed invention is not so limited, and some other embodiments may include a three-dimensional semiconductor layer 130 of island-like structures 130a of non-polygonal (e.g., curved, articulated, etc.) cross-sectional geometry. Also, in some cases, a given island-like structure 130a may have a width (e.g., as determined between the most distal vertices thereof) or diameter, for example, in the range of about 1-200 nm or greater. As previously noted, three-dimensional semiconductor layer 130 may have a thickness in the range of about 1-250 nm, in some example cases, and thus in some such instances, a given island-like structure 130a may have a height/depth in the range of about 1-250 nm or greater (e.g., about 100 nm or greater). Other suitable geometries and/or dimensions for island-like structures 130a will depend on a given application and will be apparent in light of this disclosure.

In accordance with an embodiment, the island-like structures 130a of three-dimensional semiconductor layer 130 may be formed (e.g., deposited, grown, etc.) on nucleation layer 120 using any of a wide range of techniques. For instance, in some embodiments (e.g., such as that depicted by FIG. 1A), a three-dimensional semiconductor layer 130 comprising island-like semiconductor structures 130a can be formed by deposition or epitaxial growth in a three-dimensional growth mode using processes such as, but not limited to, molecular beam epitaxy (MBE), metalorganic vapor phase epitaxy (MOVPE), etc. The formation of three-dimensional semiconductor layer 130 using such processes may be controlled, in part or in whole, by adjusting one or more growth parameters, in accordance with an embodiment. For example, when providing a three-dimensional semiconductor layer 130 comprising a plurality of island-like GaN structures 130a, it may be desirable to: (1) provide a gas flow having a low V/III ratio of trimethylgallium (Ga(CH₃)₃ or TMGa) to ammonia (NH₃); (2) provide a low growth temperature (e.g., in the range of about 500-800° C. or lower); and/or (3) provide a high growth pressure (e.g., in the range of about 100-200 torr or greater). Other suitable parameter ranges for providing a three-dimensional semiconductor layer 130 of GaN or other semiconductor material(s) will depend on a given application and will be apparent in light of this disclosure.

In some other example embodiments, a three-dimensional semiconductor layer 130 comprising island-like semiconductor structures 130a can be formed by being forced to grow in a three-dimensional mode by in-situ patterning. For instance, consider FIG. 1B, which is a side cross-sectional view of an IC 100 including a three-dimensional semiconductor layer 130 formed from a plurality of island-like structures 130a formed by in-situ patterning, in accordance with an embodiment of the present invention. As can be seen, IC 100 optionally may include an insulator layer 124 disposed on nucleation layer 120. In some cases in which nucleation layer 120 comprises AlN, for example, insulator layer 124 may comprise an insulator material such as, but not limited to, silicon dioxide (SiO₂), silicon nitride (SiNₓ), tungsten dinitride (WN₂), tungsten and titanium nitride, aluminum oxide (Al₂O₃), etc. Other suitable insulator materials for insulator layer 124 will depend on a given material composition of nucleation layer 120 and/or application of IC 100 and will be apparent in light of this disclosure.

In accordance with an embodiment, insulator layer 124 may be formed (e.g., deposited, grown, etc.) on nucleation layer 120, for example, using any of a wide range of techniques, including, but not limited to, metalorganic vapor phase epitaxy (MOVPE), etc. In some cases, insulator layer 124 may be formed as a plurality of small features (e.g., in-situ islands, patches, etc.) which may help to ensure that subsequent formation of semiconductor layer 130 is three-dimensional (e.g., consists of a plurality of island-like semiconductor structures 130a), in accordance with an embodiment. In some example instances, these small, patchy features of insulator layer 124 may have a thickness (e.g., a height/depth) in the range of about 10 nm or less (e.g., about 5-10 nm or less; about 1-5 nm or less; a monolayer; etc.). By virtue of providing such an optional insulator layer 124, the island-like structures 130a may be caused to grow or otherwise form between the features thereof, as can be seen from FIG. 1B. Other suitable configurations, geometries, and/or thicknesses for insulator layer 124 will depend on a given application and will be apparent in light of this disclosure.

It should be noted, however, that the claimed invention is not limited to only a three-dimensional semiconductor layer 130 comprising a plurality of island-like semiconductor structures 130a. For instance, in some cases, semiconductor layer 130 alternatively may comprise a plurality of nanowire structures 130b formed by being forced to grow in a three-dimensional mode by ex-situ patterning, as discussed below. For example, consider FIG. 1C, which is a side cross-sectional view of an IC 100 including a three-dimensional semiconductor layer 130 formed from a plurality of nanowires 130b formed by ex-situ patterning, in accordance with an embodiment of the present invention. As can be seen, in some embodiments, IC 100 optionally may include an insulator layer 126 disposed on nucleation layer 120 and patterned with one or more gap features 126a. In some cases in which nucleation layer 120 comprises AlN, for example, insulator layer 126 may comprise an insulator material such as, but not limited to, silicon dioxide (SiO₂), silicon nitride (SiNₓ), tungsten dinitride (WN₂), tungsten and titanium nitride, aluminum oxide (Al₂O₃), etc. Other suitable insulator materials for insulator layer 126 will depend on a given material composition of nucleation layer 120 and/or semiconductor layer 130 and/or application of IC 100 and will be apparent in light of this disclosure.

In accordance with an embodiment, insulator layer 126 may be formed (e.g., deposited, grown, etc.) on nucleation layer 120, for example, using any of a wide range of techniques, including, but not limited to, metalorganic vapor phase epitaxy (MOVPE), etc. In some cases, insulator layer 126 may be patterned with one or more gap features 126a which may help to ensure that subsequent formation of semiconductor layer 130 is three-dimensional (e.g., consists of a plurality of nanowires 130b), in accordance with an embodiment. As will be appreciated in light of this disclosure, and in accordance with an embodiment, the dimensions of a given gap feature 126a may be customized as desired, and in some example instances may have a width in the range of about 1-250 nm or greater. In some instances, a given gap feature 126a may have a height/depth in the range of about 1-250 nm or greater. By virtue of providing such an optional insulator layer 126, the nanowires 130b may be caused to grow or otherwise form within gap features 126a and to broaden/expand therefrom, as can be seen from FIG. 1C. Other suitable configurations, geometries, and/or thicknesses for insulator layer 126 will depend on a given application and will be apparent in light of this disclosure.

As will be appreciated in light of this disclosure, the dimensions of a given nanowire 130b may depend, at least in part, on the dimensions of the given gap feature 126a from which it is formed. Thus, in some cases, a given nanowire 130b may have a width in the range of about 1-250 nm or greater. Also, in some embodiments, a given nanowire 130b may have a height/depth in the range of about 1-250 nm or greater. Other suitable dimensions for a given nanowire 130b will depend on a given application and will be apparent in light of this disclosure.

By virtue of its configuration, and in accordance with an embodiment, three-dimensional semiconductor layer 130 (e.g., with its constituent plurality of island-like structures 130a, nanowires 130b, etc.) may serve to help reduce the defect density of IC 100. To illustrate, consider FIG. 1D, which is a side cross-sectional view of an IC 100 configured in accordance with an embodiment of the present invention. As can be seen, threading dislocations may be bent/terminated (e.g., annihilated or otherwise curtailed) due to dislocation interaction at any of the various interfaces where the three-dimensional semiconductor structures of semiconductor layer 130 merge/overlap. Thus, by virtue of its configuration, three-dimensional semiconductor layer 130 may function to arrest/trap threading dislocation defects near substrate 110 (e.g., within the first 20-200 nm of three-dimensional semiconductor layer 130), thereby preventing or otherwise reducing the ability of such defects to migrate through IC 100 to the top/active layer thereof. As will be appreciated in light of this disclosure, a reduction in the number of threading dislocations which are permitted to migrate to the top/active layer of IC 100 may yield a reduction in the density of surface cracks at the top/active layer of IC 100, which in turn may improve or otherwise enhance device performance, reliability, and/or yield. Furthermore, in some embodiments, three-dimensional semiconductor layer 130 may help to reduce the tensile strain state of IC 100 post-cooling.

As previously noted, IC 100 may include a two-dimensional semiconductor layer 140 on three-dimensional semiconductor layer 130, in accordance with an embodiment. In some cases, two-dimensional semiconductor layer 140 may comprise, for example, a III-N semiconductor material such as, but not limited to: (1) gallium nitride (GaN); (2) aluminum gallium nitride (AlGaN) having an Al concentration in the range of about 0% to 20% (e.g., about 10% or less); and/or (3) a combination of any of the aforementioned. However, the claimed invention is not so limited, and other suitable materials for a given two-dimensional semiconductor layer 140 will depend on a given material composition of three-dimensional semiconductor layer 130 and/or application of IC 100 and will be apparent in light of this disclosure.

In accordance with an embodiment, two-dimensional semiconductor layer 140 may be formed (e.g., deposited, grown, etc.), for example, layer by layer in a substantially two-dimensional fashion on the topology presented by the underlying three-dimensional semiconductor layer 130 using any of a wide range of techniques. Some example suitable formation techniques include, but are not limited to, molecular beam epitaxy (MBE), metalorganic vapor phase epitaxy (MOVPE), etc. Also, and in accordance with an embodiment, two-dimensional semiconductor layer 140 may be provided with any given thickness, as desired for a given application or end use. For instance, two-dimensional semiconductor layer 140 may be provided as a monolayer (e.g., having the thickness of a single atom/molecule of the semiconductor material utilized) in some embodiments, while in some other embodiments layer 140 may have a thickness in the range of about 5 nm to 5 μm or greater (e.g., in the range of about 1.2-1.5 μm or greater, or any other sub-range within the range of about 5 nm to 5 μm). Other suitable formation techniques and/or thickness ranges for two-dimensional semiconductor layer 140 will depend on a given application and will be apparent in light of this disclosure.

The formation of two-dimensional semiconductor layer 140 using such processes may be controlled, in part or in whole, by adjusting one or more growth parameters, in accordance with an embodiment. For example, when providing a two-dimensional semiconductor layer 140 comprising GaN, it may be desirable to: (1) provide a gas flow having a high V/III ratio of trimethylgallium (Ga(CH₃)₃ or TMGa) to ammonia (NH₃) (e.g., in the range of about one to ten times the V/III ratio utilized, for example, in formation of a three-dimensional semiconductor layer 130 comprising a plurality of island-like GaN structures 130a, as previously discussed); (2) provide a high growth temperature (e.g., in the range of about 800-1100° C. or lower); and/or (3) provide a low growth pressure (e.g., in the range of about 10-100 torr or lower). Other suitable growth parameter ranges for providing a two-dimensional semiconductor layer 140 of GaN or other semiconductor material(s) will depend on a given application and will be apparent in light of this disclosure.

By virtue of its configuration, a given two-dimensional semiconductor layer 140 may help, in accordance with an embodiment, to recover a desired degree of surface smoothness for IC 100 (e.g., which may have been lost due to the comparatively rough surface topology presented by the island-like structures 130a, nanowire structures 130b, etc., of three-dimensional semiconductor layer 130). As compared with existing designs/structures, some example embodiments of an IC 100 having a three-dimensional semiconductor layer 130 and an overlying two-dimensional semiconductor layer 140 may exhibit: (1) a reduced defect density; (2) a reduced surface crack density; and/or (3) improved (or otherwise preserved) surface smoothness (e.g., of the top/active layer of the structure). For instance, in some cases, IC 100 may exhibit a defect density in the range of about 2-3×10⁹/cm². Also, in some cases, IC 100 may exhibit a surface crack density of less than or equal to about 200 cracks/mm² (e.g., about 150 cracks/mm² or fewer; about 100 cracks/mm² or fewer; about 50 cracks/mm² or fewer; about 10 cracks/mm² or fewer; about 5 cracks/mm² or fewer; etc.). Furthermore, in some cases, IC 100 may exhibit a root mean square (RMS) surface roughness of less than or equal to about 5 nm (e.g., about 2 nm or less; about 1.8 nm or less; about 1.6 nm or less; etc.).

Multiple AlN Interlayer Structure

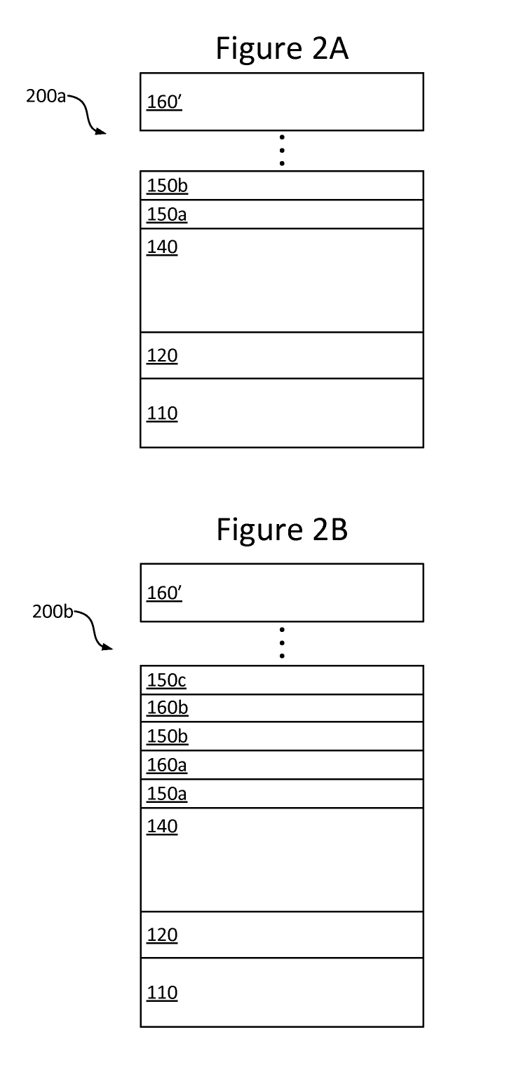

FIG. 2A is a cross-section view of an integrated circuit (IC) 200a configured in accordance with an embodiment of the present invention. As can be seen, IC 200a may include a substrate 110, a nucleation layer 120 disposed on substrate 110, and a two-dimensional semiconductor layer 140 disposed on nucleation layer 120. As will be appreciated in light of this disclosure, the discussion of suitable materials, formation techniques/processes, and configurations for substrate 110, nucleation layer 120, and semiconductor layer 140 provided above with reference to FIGS. 1A-1D may be applied equally here. As can further be seen, and in accordance with an embodiment, one or more semiconductor layers 150 (150a, 150b, etc.) may be provided (e.g., stacked together in an adjacent or otherwise neighboring fashion) on semiconductor layer 140, and a final semiconductor layer 160′ (discussed below) may be disposed on the last or otherwise upper-most of such semiconductor layers 150. As will be further appreciated in light of this disclosure, IC 200a may include additional, fewer, and/or different elements or components from those here described (e.g., in some embodiments, IC 200a may not include any semiconductor layers 150 and/or a final semiconductor layer 160′), and the claimed invention is not intended to be limited to any particular IC configurations, but can be used with numerous configurations in numerous applications.

In accordance with an embodiment, a given semiconductor layer 150 (150a, 150b, etc.) may comprise any of a wide range of semiconductor materials. Some example suitable materials may include, but are not necessarily limited to: (1) aluminum gallium nitride (AlGaN); (2) aluminum indium nitride (AlInN); (3) gallium nitride (GaN); and/or (4) a combination of any of the aforementioned. Other suitable materials for a given semiconductor layer 150 (150a, 150b, etc.) will depend on a given material composition of the underlying and/or otherwise adjacent layer (e.g., semiconductor layer 140, a neighboring semiconductor layer 150, etc.) and/or application of IC 200a and will be apparent in light of this disclosure.

As will be appreciated in light of this disclosure, as the temperature of IC 200a decreases (e.g., is ramped down during the fabrication process), the stacked structure may come under tensile stress, for example, due to the thermal mismatch of the semiconductor material of layer 140 and substrate 110 (e.g., in some cases in which GaN and Si are utilized, the thermal mismatch there between may be about 116% or greater, as previously noted). However, inclusion of the one or more semiconductor layers 150 (150a, 150b, etc.) may serve to induce compressive stress, for example, in the two-dimensional semiconductor layer 140 and thus aid in changing the stress state of the structure to a compressive one at the end of fabrication of IC 200a (e.g., during cool-down thereof after epitaxial growth). By virtue of this balancing between tensile and compressive stresses, surface cracks in the top/active layer of IC 200a may be eliminated altogether, in some cases, or otherwise substantially reduced.

In accordance with an embodiment, a given semiconductor layer 150 (150a, 150b, etc.) may be formed (e.g., deposited, grown, etc.) on an underlying layer using any of a wide range of techniques. For instance, in some cases, a given semiconductor layer 150 may be formed by epitaxial growth using processes such as, but not limited to, molecular beam epitaxy (MBE), metalorganic vapor phase epitaxy (MOVPE), etc. As will be appreciated in light of this disclosure, and in accordance with an embodiment, the formation of a given semiconductor layer 150 using such processes may be controlled, in part or in whole, by adjusting one or more of the growth parameters, including, but not limited to: (1) gas flow; (2) growth temperature; and/or (3) pressure. For instance, to aid in reducing surface cracks, it may be desirable, in some cases, to form a given semiconductor layer 150 at a growth temperature in the range of about 250-1000° C. or lower (e.g., about 500-600° C.; about 600-700° C.; about 700-800° C.; or any other sub-range within the range of about 500-800° C.). Other suitable techniques for providing a given semiconductor layer 150 will depend on a given application and will be apparent in light of this disclosure.

In accordance with an embodiment, a given semiconductor layer 150 (150a, 150b, etc.) may be provided with any thickness, as desired for a given application or end use. In some embodiments, a given semiconductor layer 150 may have a thickness, for example, in the range of about 1-100 nm or greater (e.g., about 20 nm or less; about 50 nm or less; about 80 nm or less; or any other sub-range within the range of about 1-100 nm or greater). In some example cases in which a given semiconductor layer 150 comprises AlGaN having a high concentration of Al (e.g., greater than about 5%), for instance, such semiconductor layer 150 may have a thickness in the range of about 1-20 nm or less. In some example cases in which a given semiconductor layer 150 comprises AlGaN having a low concentration of Al (e.g., less than or equal to about 5%), for instance, such semiconductor layer 150 may have a thickness in the range of about 10-100 nm or less. As will be appreciated in light of this disclosure, any quantity of semiconductor layers 150 may be stacked together in IC 200a. In some cases, a given semiconductor layer 150 may have a substantially uniform thickness across the topology provided by an underlying layer (e.g., a two-dimensional semiconductor layer 140, a neighboring semiconductor layer 150, etc.). However, the claimed invention is not so limited, as in some other instances, a given semiconductor layer 150 may be provided with a non-uniform or otherwise varying thickness over such topology. For instance, in some cases a first portion of a semiconductor layer 150 may have a thickness within a first range while a second portion thereof has a thickness within a second, different range. Other suitable formation techniques and/or thickness ranges for a given individual and/or stack of semiconductor layers 150 (150a, 150b, etc.) will depend on a given application and will be apparent in light of this disclosure.

In some cases, and in accordance with an embodiment, one or more additional two-dimensional semiconductor layers may be dispersed in a stacked configuration like that of IC 200a. For instance, consider FIG. 2B, which is a cross-section view of an integrated circuit (IC) 200b configured in accordance with an embodiment of the present invention. As can be seen, IC 200b is configured in much the same way as IC 200a with an example difference being that the semiconductor layers 150 (150a, 150b, etc.) of IC 200b may be provided in a dispersed configuration by virtue of including a two-dimensional semiconductor layer 160 (160a, 160b, etc.) between neighboring semiconductor layers 150. For instance, a first two-dimensional semiconductor layer 160a may be disposed between neighboring semiconductor layers 150a and 150b, a second two-dimensional semiconductor layer 160b may be disposed between neighboring semiconductor layers 150b and 150c, and so on as desired. As can further be seen, a final semiconductor layer 160′ may be disposed on the last of such semiconductor layers 150 (150a, 150b, etc.) of IC 200b. As will be appreciated in light of this disclosure, IC 200b may include additional, fewer, and/or different elements or components from those here described, and the claimed invention is not intended to be limited to any particular IC configurations, but can be used with numerous configurations in numerous applications.

In accordance with an embodiment, the discussion provided above with reference to FIGS. 1A-1D of the materials, formation techniques/processes, and configurations for two-dimensional semiconductor layer 140 may be applied equally here in the context of the one or more semiconductor layers 160 (160a, 160b, 160′, etc.). Also, in accordance with an embodiment, a given semiconductor layer 160 may be provided with any given thickness, as desired for a given application or end use. In some embodiments, a given semiconductor layer 160 may have a thickness in the range of about 10-1000 nm or greater. Other suitable materials, formation techniques/process, thicknesses, and/or configurations for a given semiconductor layer 160 (160a, 160b, 160′, etc.) will depend on a given application and will be apparent in light of this disclosure.

Three-Dimensional and Two-Dimensional GaN with Multiple AlN Interlayer Structure

In some cases, and in accordance with an embodiment, the structure of IC 100 may be integrated with the structure of IC 200a/200b to provide an IC 300a/300b (discussed below) which may exhibit, for example: (1) a reduced defect density; (2) a reduced surface crack density (e.g., no cracks or an otherwise minimal presence thereof); and/or (3) a substantially smooth top/active layer surface.

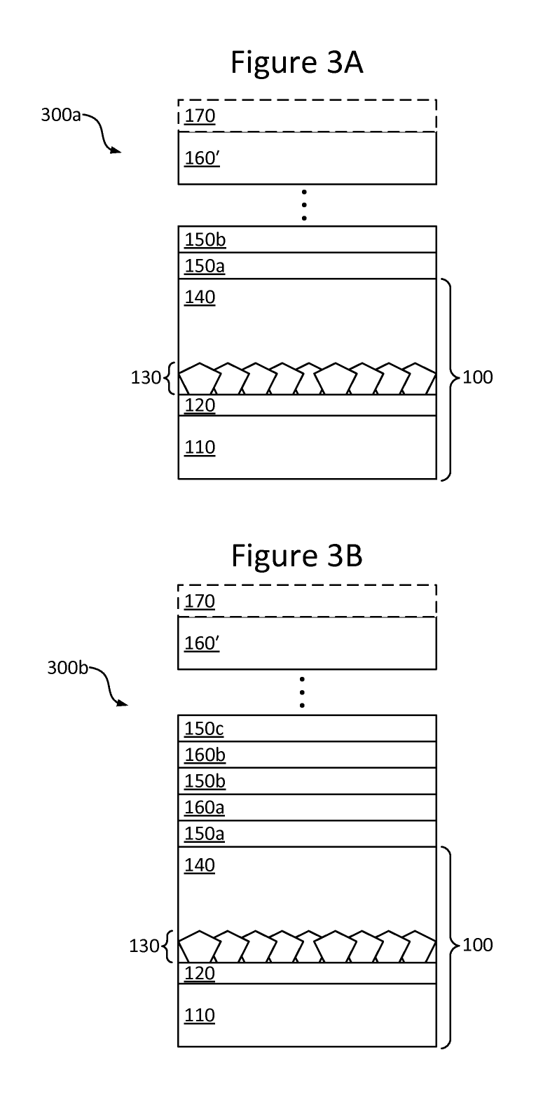

FIG. 3A is a cross-section view of an integrated circuit (IC) 300a configured in accordance with an embodiment of the present invention. As can be seen, IC 300a may include a substrate 110, a nucleation layer 120 disposed on substrate 110, a three-dimensional semiconductor layer 130 disposed on nucleation layer 120, and a two-dimensional semiconductor layer 140 disposed on three-dimensional semiconductor layer 130, as similarly discussed above in the context of FIGS. 1A-1D. As will be appreciated in light of this disclosure, the discussion of suitable materials, formation techniques/processes, and configurations for substrate 110, nucleation layer 120, three-dimensional semiconductor layer 130, and two-dimensional semiconductor layer 140 provided above with reference to FIGS. 1A-1D and FIGS. 2A-2B may be applied equally here.

As can be further seen from FIG. 3A, in some embodiments, IC 300a may include one or more semiconductor layers 150 (150a, 150b, etc.) disposed on the two-dimensional semiconductor layer 140. In some embodiments, IC 300a may include a final semiconductor layer 160′ disposed on the last or otherwise uppermost of the one or more semiconductor layers 150. Furthermore, in some embodiments, IC 300a may include an optional capping layer 170 (discussed below) disposed on the final semiconductor layer 160′. As will be appreciated in light of this disclosure, IC 300a may include additional, fewer, and/or different elements or components from those here described, and the claimed invention is not intended to be limited to any particular IC configurations, but can be used with numerous configurations in numerous applications.

FIG. 3B is a cross-section view of an integrated circuit (IC) 300b configured in accordance with an embodiment of the present invention. As can be seen, IC 300b is configured in much the same way as IC 300a with an example difference being that the semiconductor layers 150 (150a, 150b, etc.) of IC 300b may be provided in a dispersed configuration by virtue of including a two-dimensional semiconductor layer 160 (160a, 160b, etc.) between neighboring semiconductor layers 150. For instance, a first two-dimensional semiconductor layer 160a may be disposed between neighboring semiconductor layers 150a and 150b, a second two-dimensional semiconductor layer 160b may be disposed between neighboring semiconductor layers 150b and 150c, and so on as desired. As can further be seen, a final semiconductor layer 160′ may be disposed on the last of such semiconductor layers 150 (150a, 150b, etc.) of IC 300b. Still further, in some embodiments, IC 300b may include an optional capping layer 170 (discussed below) disposed on the final semiconductor layer 160′. As will be appreciated in light of this disclosure, IC 300b may include additional, fewer, and/or different elements or components from those here described, and the claimed invention is not intended to be limited to any particular IC configurations, but can be used with numerous configurations in numerous applications.

As previously noted, and as can be seen from FIGS. 3A-3B, IC 300a/300b optionally may include a capping layer 170 disposed on the final semiconductor layer 160′. As will be appreciated in light of this disclosure, and in accordance with an embodiment, the optional capping layer 170 may be customized as desired for a given application or end use of IC 300a/300b. For instance, in some cases (e.g., such as in electronic device applications), a capping layer 170 comprising aluminum indium nitride (AlInN) or AlGaN may be provided. In some other cases (e.g., such as for optoelectronics applications), a capping layer 170 comprising indium gallium nitride (InGaN) or AlGaN may be provided. Other suitable materials for a given optional capping layer 170 will depend on a given application and will be apparent in light of this disclosure.

In accordance with an embodiment, optional capping layer 170 may be formed (e.g., deposited, grown, etc.) on the final semiconductor layer 160′ using any of a wide range of techniques. Some example suitable formation techniques include, but are not limited to, molecular beam epitaxy (MBE), metalorganic vapor phase epitaxy (MOVPE), etc. Also, and in accordance with an embodiment, optional capping layer 170 may be provided with any given thickness, as desired for a given application or end use. In some embodiments, optional capping layer 170 may have a thickness in the range of about 1-50 nm or greater (e.g., about 2-25 nm or greater, or any other sub-range within the range of about 1-50 nm). In some cases, optional capping layer 170 may have a substantially uniform thickness across the topology provided by the underlying final semiconductor layer 160′. However, the claimed invention is not so limited, as in some other instances, optional capping layer 170 may be provided with a non-uniform or otherwise varying thickness over such topology. For instance, in some cases a first portion of optional capping layer 170 may have a thickness within a first range while a second portion thereof has a thickness within a second, different range. Other suitable formation techniques and/or thickness ranges for optional capping layer 170 will depend on a given application and will be apparent in light of this disclosure.

Example System

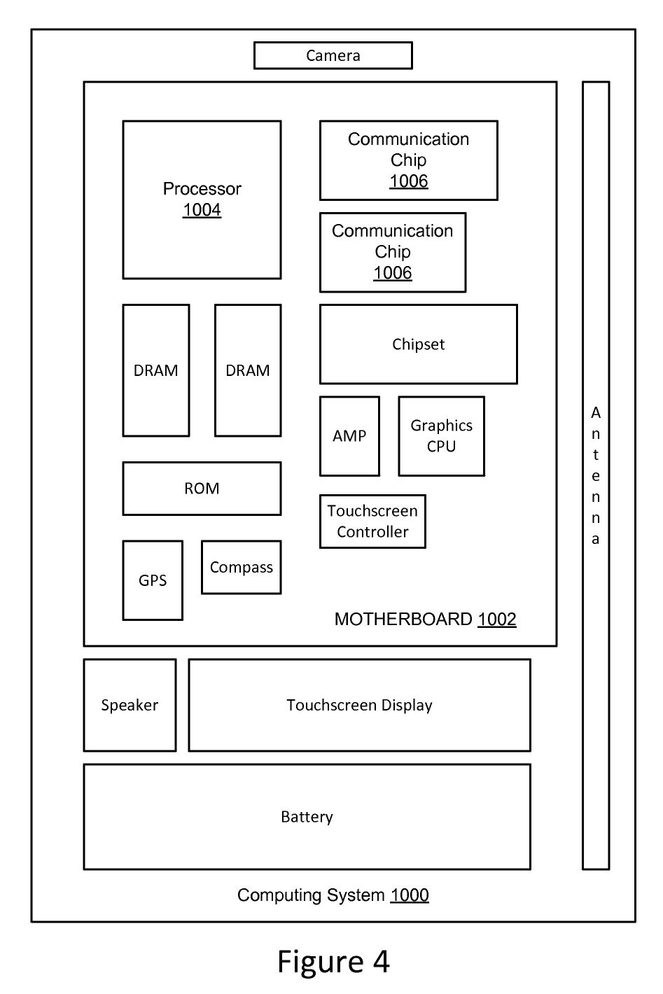

FIG. 4 illustrates a computing system 1000 implemented with integrated circuit structures or devices formed by one or more of the defect density and/or crack density reduction techniques disclosed herein, in accordance with an example embodiment of the present invention. As can be seen, the computing system 1000 houses a motherboard 1002. The motherboard 1002 may include a number of components, including, but not limited to, a processor 1004 and at least one communication chip 1006, each of which can be physically and electrically coupled to the motherboard 1002, or otherwise integrated therein. As will be appreciated, the motherboard 1002 may be, for example, any printed circuit board, whether a main board, a daughterboard mounted on a main board, or the only board of system 1000, etc. Depending on its applications, computing system 1000 may include one or more other components that may or may not be physically and electrically coupled to the motherboard 1002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1000 may include one or more integrated circuit structures or devices formed by one or more of the defect density and/or crack density reduction techniques disclosed herein in accordance with an example embodiment of the present invention. In some embodiments, multiple functions can be integrated into one or more chips (e.g., for instance, note that the communication chip 1006 can be part of or otherwise integrated into the processor 1004).

The communication chip 1006 enables wireless communications for the transfer of data to and from the computing system 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing system 1000 includes an integrated circuit die packaged within the processor 1004. In some embodiments of the present invention, the integrated circuit die of the processor includes onboard memory circuitry that is implemented with one or more integrated circuit structures or devices formed by one or more of the defect density and/or crack density reduction techniques, as variously described herein. The term “processor” may refer to any device or portion of a device that processes, for instance, electronic data from registers and/or memory to transform that electronic data into other electronic data that may be stored in registers and/or memory.

The communication chip 1006 also may include an integrated circuit die packaged within the communication chip 1006. In accordance with some such example embodiments, the integrated circuit die of the communication chip includes one or more integrated circuit structures or devices formed by one or more of the defect density and/or crack density reduction techniques as described herein. As will be appreciated in light of this disclosure, note that multi-standard wireless capability may be integrated directly into the processor 1004 (e.g., where functionality of any chips 1006 is integrated into processor 1004, rather than having separate communication chips). Further note that processor 1004 may be a chip set having such wireless capability. In short, any number of processor 1004 and/or communication chips 1006 can be used. Likewise, any one chip or chip set can have multiple functions integrated therein.

In various implementations, the computing device 1000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed by one or more of the defect density and/or crack density reduction techniques, as variously described herein.

Numerous embodiments will be apparent in light of this disclosure. One example embodiment of the present invention provides an integrated circuit including a crystalline silicon substrate, a nucleation layer on the substrate, and a first semiconductor layer formed on the nucleation layer, the first semiconductor layer including a three-dimensional gallium nitride (GaN) layer on the nucleation layer and having a plurality of three-dimensional semiconductor structures and a two-dimensional GaN layer on the three-dimensional GaN layer. In some cases, the nucleation layer includes at least one of aluminum nitride (AlN), aluminum gallium nitride (AlGaN), and/or a combination of any of the aforementioned, and the integrated circuit further includes a patterned insulator layer on the nucleation layer, the patterned insulator layer including at least one of silicon dioxide (SiO₂), silicon nitride (SiNₓ), tungsten dinitride (WN₂), tungsten and titanium nitride, aluminum oxide (Al₂O₃), and/or a combination of any of the aforementioned. In some cases, the integrated circuit further includes a second semiconductor layer formed on or within the first semiconductor layer, wherein the second semiconductor layer includes aluminum gallium nitride (AlGaN) on the two-dimensional GaN layer and a GaN layer on the AlGaN layer. In some such cases, the second semiconductor layer includes multiple alternating layers of AlGaN and GaN. In some other such cases, the second semiconductor layer is within the two-dimensional GaN layer. In some instances, the three-dimensional GaN layer includes at least one of a plurality of island-like semiconductor structures and/or a plurality of nanowires. In some instances, the substrate has a crystal orientation of [100]. In some cases, the integrated circuit further includes a capping layer including at least one of AlGaN, aluminum indium nitride (AlInN), and/or indium gallium nitride (InGaN). In some example instances, the integrated circuit exhibits at least one of a defect density of about 3×10⁹/cm² or less, a surface crack density of about 200 cracks/mm² or fewer, and/or a root mean square (RMS) surface roughness of about 5 nm or less. In some cases, a system-on-chip including the integrated circuit is provided. In some cases, a mobile computing system including the integrated circuit is provided.

Another example embodiment of the present invention provides an integrated circuit including a crystalline silicon substrate, a nucleation layer on the substrate, a first semiconductor layer formed on the nucleation layer, the first semiconductor layer comprising a two-dimensional gallium nitride (GaN) layer on the nucleation layer, and a second semiconductor layer formed on or within the first semiconductor layer, wherein the second semiconductor layer includes an aluminum gallium nitride (AlGaN) layer on the two-dimensional GaN layer and a GaN layer on the AlGaN layer. In some cases, the nucleation layer includes at least one of aluminum nitride (AlN), aluminum gallium nitride (AlGaN), and/or a combination of any of the aforementioned. In some cases, the second semiconductor layer includes multiple alternating layers of AlGaN and GaN. In some instances, the second semiconductor layer is within the two-dimensional GaN layer. In some instances, the substrate has a crystal orientation of [100]. In some cases, the integrated circuit further includes a capping layer including at least one of AlGaN, aluminum indium nitride (AlInN), and/or indium gallium nitride (InGaN). In some example instances, the integrated circuit exhibits at least one of a defect density of about 3×10⁹/cm² or less, a surface crack density of about 200 cracks/mm² or fewer, and/or a root mean square (RMS) surface roughness of about 5 nm or less. In some cases, a system-on-chip including the integrated circuit is provided. In some cases, a mobile computing system including the integrated circuit is provided.

Another example embodiment of the present invention provides a method of forming an integrated circuit, the method including forming a nucleation layer on a crystalline silicon substrate and forming a first semiconductor layer on the nucleation layer, the first semiconductor layer including either a three-dimensional gallium nitride (GaN) layer on the nucleation layer and having a plurality of three-dimensional semiconductor structures and a two-dimensional GaN layer on the three-dimensional GaN layer or a two-dimensional GaN layer on the nucleation layer, wherein in response to the first semiconductor layer including a two-dimensional GaN layer on the nucleation layer, the method further includes forming a second semiconductor layer on or within the first semiconductor layer, wherein the second semiconductor layer includes an aluminum gallium nitride (AlGaN) layer on the two-dimensional GaN layer and a GaN layer on the AlGaN layer. In some cases, the method further includes forming a patterned insulator layer on the nucleation layer prior to forming the first semiconductor layer, wherein the patterned insulator layer includes at least one of silicon dioxide (SiO₂), silicon nitride (SiNₓ), tungsten dinitride (WN₂), tungsten and titanium nitride, aluminum oxide (Al₂O₃), and/or a combination of any of the aforementioned. In some instances, forming the first semiconductor layer includes an in-situ patterning process. In some other instances, forming the first semiconductor layer includes an ex-situ patterning process. In some cases, at least one semiconductor layer is formed using at least one of a molecular beam epitaxy (MBE) process and/or a metalorganic vapor phase epitaxy (MOVPE) process.

The foregoing description of the embodiments of the invention has been presented for the purposes of illustration and description. It is not intended to be exhaustive or to limit the invention to the precise form disclosed. Many modifications and variations are possible in light of this disclosure. It is intended that the scope of the invention be limited not by this detailed description, but rather by the claims appended hereto.

What is claimed is:

1. An integrated circuit comprising:
a crystalline silicon substrate;
a nucleation layer on the substrate; and
a first semiconductor layer formed on the nucleation layer, the first semiconductor layer comprising:
a three-dimensional gallium nitride (GaN) layer on the nucleation layer and having a plurality of three-dimensional semiconductor structures; and
a two-dimensional GaN layer on the three-dimensional GaN layer.

2. The integrated circuit of claim 1, wherein the nucleation layer comprises at least one of aluminum nitride (AlN), aluminum gallium nitride (AlGaN), and/or a combination of any of the aforementioned, and wherein the integrated circuit further comprises a patterned insulator layer on the nucleation layer, the patterned insulator layer comprising at least one of silicon dioxide (SiO₂), silicon nitride (SiNₓ), tungsten dinitride (WN₂), tungsten and titanium nitride, aluminum oxide (Al₂O₃), and/or a combination of any of the aforementioned.

3. The integrated circuit of claim 1 further comprising a second semiconductor layer formed on or within the first semiconductor layer, wherein the second semiconductor layer comprises aluminum gallium nitride (AlGaN) on the two-dimensional GaN layer and a GaN layer on the AlGaN layer.

4. The integrated circuit of claim 3, wherein the second semiconductor layer includes multiple alternating layers of AlGaN and GaN.

5. The integrated circuit of claim 3, wherein the second semiconductor layer is within the two-dimensional GaN layer.

6. The integrated circuit of claim 1, wherein the three-dimensional GaN layer comprises at least one of a plurality of island-like semiconductor structures and/or a plurality of nanowires.

7. The integrated circuit of claim 1, wherein the substrate has a crystal orientation of [100].

8. The integrated circuit of claim 1 further comprising a capping layer including at least one of AlGaN, aluminum indium nitride (AlInN), and/or indium gallium nitride (InGaN).

9. The integrated circuit of claim 1, wherein the integrated circuit exhibits at least one of a defect density of about 3×10⁹/cm² or less, a surface crack density of about 200 cracks/mm² or fewer, and/or a root mean square (RMS) surface roughness of about 5 nm or less.

10. A system-on-chip comprising the integrated circuit of claim 1.

11. A mobile computing system comprising the integrated circuit of claim 1.

12. An integrated circuit comprising:
a crystalline silicon substrate;
a nucleation layer on the substrate;
a first semiconductor layer formed on the nucleation layer, the first semiconductor layer comprising a two-dimensional gallium nitride (GaN) layer on the nucleation layer; and
a second semiconductor layer formed on or within the first semiconductor layer, wherein the second semiconductor layer comprises:
an aluminum gallium nitride (AlGaN) layer on the two-dimensional GaN layer; and
a GaN layer on the AlGaN layer.

13. The integrated circuit of claim 12, wherein the nucleation layer comprises at least one of aluminum nitride (AlN), aluminum gallium nitride (AlGaN), and/or a combination of any of the aforementioned.

14. The integrated circuit of claim 12, wherein the second semiconductor layer includes multiple alternating layers of AlGaN and GaN.

15. The integrated circuit of claim 12, wherein the second semiconductor layer is within the two-dimensional GaN layer.

16. The integrated circuit of claim 12, wherein the substrate has a crystal orientation of [100].

17. The integrated circuit of claim 12 further comprising a capping layer including at least one of AlGaN, aluminum indium nitride (AlInN), and/or indium gallium nitride (InGaN).

18. The integrated circuit of claim 12, wherein the integrated circuit exhibits at least one of a defect density of about 3×10⁹/cm² or less, a surface crack density of about 200 cracks/mm² or fewer, and/or a root mean square (RMS) surface roughness of about 5 nm or less.

19. A system-on-chip comprising the integrated circuit of claim 12.

20. A mobile computing system comprising the integrated circuit of claim 12.

21. A method of forming an integrated circuit, the method comprising:
forming a nucleation layer on a crystalline silicon substrate; and
forming a first semiconductor layer on the nucleation layer, the first semiconductor layer comprising either:
a three-dimensional gallium nitride (GaN) layer on the nucleation layer and having a plurality of three-dimensional semiconductor structures and a two-dimensional GaN layer on the three-dimensional GaN layer; or
a two-dimensional GaN layer on the nucleation layer;
wherein in response to the first semiconductor layer including a two-dimensional GaN layer on the nucleation layer, the method further comprises forming a second semiconductor layer on or within the first semiconductor layer, wherein the second semiconductor layer comprises an aluminum gallium nitride (AlGaN) layer on the two-dimensional GaN layer and a GaN layer on the AlGaN layer.

22. The method of claim 21 further comprising forming a patterned insulator layer on the nucleation layer prior to forming the first semiconductor layer, wherein the patterned insulator layer comprises at least one of silicon dioxide (SiO₂), silicon nitride (SiNₓ), tungsten dinitride (WN₂), tungsten and titanium nitride, aluminum oxide (Al₂O₃), and/or a combination of any of the aforementioned.

23. The method of claim 21, wherein forming the first semiconductor layer comprises an in-situ patterning process.

24. The method of claim 21, wherein forming the first semiconductor layer comprises an ex-situ patterning process.

25. The method of claim 21, wherein at least one semiconductor layer is formed using at least one of a molecular beam epitaxy (MBE) process and/or a metalorganic vapor phase epitaxy (MOVPE) process.
